(19) United States
(12) Patent Application Publication
(10) Pub. No.: US 2012/0015499 A1
(43) Pub. Date: Jan. 19, 2012

(54) METHOD FOR MANUFACTURING SEMICONDUCTOR SUBSTRATE

(75) Inventors: Makoto Sasaki, Hyogo (JP); Shin Harada, Osaka (JP); Taro Nishiguchi, Hyogo (JP); Kyoko Okita, Osaka (JP); Yasuo Namikawa, Osaka (JP)

(73) Assignee: SUMITOMO ELECTRIC INDUSTRIES, LTD., Osaka-shi, Osaka (JP)

(21) Appl. No.: 13/256,328

(22) PCT Filed: Sep. 28, 2010
(86) PCT No.: PCT/JP2010/066831

§ 371 Date: Sep. 13, 2011

(30) Foreign Application Priority Data
Nov. 13, 2009 (JP) 2009-259674

(51) Int. Cl. H01L 21/04

(52) U.S. Cl. 438/458; 257/E21.054

(57) ABSTRACT

A combined substrate is prepared which has a supporting portion and first and second silicon carbide substrates. Between the first and second silicon carbide substrates, a gap having an opening exists. A closing layer for the gap is formed over the opening. The closing layer at least includes a silicon layer. In order to form a cover made of silicon carbide and closing the gap over the opening, the silicon layer is carbonized. By depositing sublimates from the first and second side surfaces of the first and second silicon carbide substrates onto the cover, a connecting portion is formed to close the opening. The cover is removed.

### TECHNICAL FIELD

The present invention relates to a method for manufacturing a semiconductor substrate, in particular, a method for manufacturing a semiconductor substrate including a portion made of silicon carbide (SiC) having a single-crystal structure.

### BACKGROUND ART

In recent years, SiC substrates have been adopted as semiconductor substrates for use in manufacturing semiconductor devices. SiC has a band gap larger than that of Si (silicon), which has been used more commonly. Hence, a semiconductor device employing a SiC substrate advantageously has a large reverse breakdown voltage, low on-resistance, or has properties less likely to decrease in a high temperature environment.

In order to efficiently manufacture such semiconductor devices, the substrates need to be large in size to some extent. According to U.S. Pat. No. 7,314,520 (Patent Document 1), a SiC substrate of 76 mm (3 inches) or greater can be manufactured.

### PRIOR ART DOCUMENTS

### Patent Documents

Patent Document 1: Patent Document 1: U.S. Pat. No. 7,314,520

### SUMMARY OF THE INVENTION

### Problems to be Solved by the Invention

Industrially, the size of a SiC substrate is still limited to approximately 100 mm (4 inches). Accordingly, semiconductor devices cannot be efficiently manufactured using large substrates, disadvantageously. This disadvantage becomes particularly serious in the case of using a property of a plane other than the (0001) plane in SiC of hexagonal system. Hereinafter, this will be described.

A SiC substrate small in defect is usually manufactured by slicing a SiC ingot obtained by growth in the (0001) plane, which is less likely to cause stacking fault. Hence, a SiC substrate having a plane orientation other than the (0001) plane is obtained by slicing the ingot not in parallel with its grown surface. This makes it difficult to sufficiently secure the size of the substrate, or many portions in the ingot cannot be used effectively. For this reason, it is particularly difficult to effectively manufacture a semiconductor device that employs a plane other than the (0001) plane of SiC.

Instead of increasing the size of such a SiC substrate with difficulty, it is considered to use a semiconductor substrate having a supporting portion and a plurality of small SiC substrates disposed thereon. The size of this semiconductor substrate can be increased by increasing the number of SiC substrates as required.

However, in this semiconductor substrate, gaps are formed between adjacent SiC substrates. In the gaps, foreign matters are likely to be accumulated during a process of manufacturing a semiconductor device using the semiconductor substrate. An exemplary foreign matter is: a cleaning liquid or polishing agent used in the process of manufacturing a semiconductor device; or dust in the atmosphere. Such foreign matters result in decreased manufacturing yield, which leads to decreased efficiency of manufacturing semiconductor devices, disadvantageously.

The present invention is made in view of the foregoing problems and its object is to provide a method for manufacturing a large semiconductor substrate allowing for manufacturing of semiconductor devices with a high yield.

### Means for Solving the Problems

A method according to the present invention for manufacturing a semiconductor substrate includes the following steps.

First, there is prepared a combined substrate having a supporting portion, a first silicon carbide substrate having a single-crystal structure, and a second silicon carbide substrate having a single-crystal structure. The first silicon carbide substrate has a first backside surface connected to the supporting portion, a first front-side surface opposite to the first backside surface, and a first side surface connecting the first backside surface and the first front-side surface. The second silicon carbide substrate has a second backside surface connected to the supporting portion, a second front-side surface opposite to the second backside surface, and a second side surface connecting the second backside surface and the second front-side surface. The second side surface is disposed such that a gap having an opening between the first and second front-side surfaces is formed between the first side surface and the second side surface. Then, a closing layer is formed to close the gap over the opening. The closing layer includes at least a silicon layer. Then, the silicon layer is carbonized to form a cover made of silicon carbide and closing the gap over the opening. Then, a connecting portion for connecting the first and second side surfaces is formed so as to close the opening by depositing a sublimate from the first and second side surfaces onto the cover. The cover is removed after the step of forming the connecting portion.

According to this manufacturing method, the opening of the gap between the first and second silicon carbide substrates is closed. Hence, upon manufacturing a semiconductor device using the semiconductor substrate, foreign matters are not accumulated in the gap. This prevents yield from being decreased by the foreign matters, thus obtaining a semiconductor substrate allowing for manufacturing of semiconductor devices with a high yield.

Further, the cover on which the sublimate is deposited to close the opening is made of silicon carbide. Namely, the cover and the first and second silicon carbide substrates are all made of silicon carbide. Accordingly, the cover can be provided with a crystal structure close to that of each of the first and second silicon carbide substrates. Hence, the connecting portion formed on the cover can be also provided with a crystal structure close to that of each of the first and second single-crystal substrates. As a result, the crystal structure of each of the first and second silicon carbide substrates and the crystal structure of the connecting portion are close to each other. Accordingly, the connecting portion provides firm connection between the first and second silicon carbide substrates.

Further, the cover made of silicon carbide is formed using the silicon layer, which can be readily formed as compared with formation of a silicon carbide layer. Accordingly, the semiconductor substrate can be manufactured more readily as compared with a case of directly forming a cover made of silicon carbide.

In the above-described method for manufacturing the semiconductor substrate, preferably, the step of carbonizing the silicon layer includes the step of supplying the silicon layer with a gas containing carbon element. Accordingly, the cover made of silicon carbide can be readily formed.

In the above-described method for manufacturing the semiconductor substrate, preferably, the step of forming the closing layer includes the step of providing a carbon layer. The step of carbonizing the silicon layer includes the step of chemically combining silicon contained in the silicon layer with carbon contained in the carbon layer. Accordingly, the cover made of silicon carbide can be readily formed.

In the above-described method for manufacturing the semiconductor substrate, preferably, the step of providing the carbon layer includes the step of depositing a layer made of carbon. Accordingly, the carbon layer can be formed securely.

In the above-described method for manufacturing the semiconductor substrate, preferably, the step of providing the carbon layer includes steps of: applying a fluid (FIG. 12: 70L) containing carbon element; and carbonizing the fluid. Accordingly, the carbon layer can be provided by the readily implementable steps such as the application and carbonization.

In the above-described method for manufacturing the semiconductor substrate, preferably, the fluid is a liquid containing an organic substance. Accordingly, the fluid can be applied uniformly.

In the above-described method for manufacturing the semiconductor substrate, preferably, the fluid is a suspension containing a carbon powder. Accordingly, by removing liquid component of the suspension, the fluid can be readily carbonized.

In the above-described method for manufacturing the semiconductor substrate, preferably, the supporting portion is made of silicon carbide, as with the first and second silicon carbide substrates. Accordingly, the supporting portion can be provided with properties close to those of the first and second silicon carbide substrates.

The above-described method for manufacturing the semiconductor substrate preferably further includes the step of depositing the sublimate from the supporting portion onto the connecting portion in the gap having the opening closed by the connecting portion. Accordingly, the connecting portion can be thicker.

In the method for manufacturing the semiconductor substrate, preferably, the step of depositing the sublimate from the supporting portion onto the connecting portion is performed to bring, into the supporting portion, the whole of the gap having the opening closed by the connecting portion. Accordingly, the connecting portion can be thicker.

The method for manufacturing the semiconductor substrate preferably further includes the step of polishing each of the first and second front-side surfaces. Accordingly, the first and second front-side surfaces, which serve as the surface of the semiconductor substrate, can be flat. Hence, a high-quality film can be formed on this flat surface of the semiconductor substrate.

In the method for manufacturing the semiconductor substrate, preferably, each of the first and second backside surfaces is a surface formed through slicing. Namely, each of the first and second backside surfaces is a surface formed through slicing and not polished after the slicing. Thus, undulations are provided on each of the first and second backside surfaces. Hence, a space in a recess of the undulations can be used as a space in which the sublimation gas is spread in the case where the sublimation method is employed to provide the supporting portion on the first and second backside surfaces.

In the method for manufacturing the semiconductor substrate, preferably, the step of forming the connecting portion is performed in an atmosphere having a pressure higher than 10⁻¹ Pa and lower than 10⁴ Pa.

### Effects of the Invention

As apparent from the description above, the present invention can provide a method for manufacturing a large semiconductor substrate allowing for manufacturing of semiconductor devices with a high yield.

### BRIEF DESCRIPTION OF THE DRAWINGS

FIG. 1 is a plan view schematically showing a configuration of a semiconductor substrate in a first embodiment of the present invention.

FIG. 2 is a schematic cross sectional view taken along a line II-II in FIG. 1.

FIG. 3 is a plan view schematically showing a first step of a method for manufacturing the semiconductor substrate in the first embodiment of the present invention.

FIG. 4 is a schematic cross sectional view taken along a line IV-IV in FIG. 3.

FIG. 5 is a cross sectional view schematically showing a second step of the method for manufacturing the semiconductor substrate in the first embodiment of the present invention.

FIG. 6 is a cross sectional view schematically showing a third step of the method for manufacturing the semiconductor substrate in the first embodiment of the present invention.

FIG. 7 is a partial cross sectional view schematically showing a fourth step of the method for manufacturing the semiconductor substrate in the first embodiment of the present invention.

FIG. 8 is a partial cross sectional view schematically showing a fifth step of the method for manufacturing the semiconductor substrate in the first embodiment of the present invention.

FIG. 9 is a cross sectional view schematically showing a sixth step of the method for manufacturing the semiconductor substrate in the first embodiment of the present invention.

FIG. 10 is a partial cross sectional view schematically showing one step of a method for manufacturing a semiconductor substrate in a comparative example.

FIG. 11 is a cross sectional view schematically showing one step of a method for manufacturing a semiconductor substrate in a second embodiment of the present invention.

FIG. 12 is a cross sectional view schematically showing one step of a method for manufacturing a semiconductor substrate in a variation of the second embodiment of the present invention.

FIG. 13 is a cross sectional view schematically showing a first step of a method for manufacturing a semiconductor substrate in a third embodiment of the present invention.

FIG. 14 is a cross sectional view schematically showing a second step of the method for manufacturing the semiconductor substrate in the third embodiment of the present invention.

FIG. 15 is a cross sectional view schematically showing a third step of the method for manufacturing the semiconductor substrate in the third embodiment of the present invention.

FIG. 16 is a cross sectional view schematically showing one step of a method for manufacturing a semiconductor substrate in a first variation of the third embodiment of the present invention.

FIG. 17 is a cross sectional view schematically showing one step of a method for manufacturing a semiconductor substrate in a second variation of the third embodiment of the present invention.

FIG. 18 is a cross sectional view schematically showing one step of a method for manufacturing a semiconductor substrate in a third variation of the third embodiment of the present invention.

FIG. 19 is a plan view schematically showing a configuration of a semiconductor substrate in a fourth embodiment of the present invention.

FIG. 20 is a schematic cross sectional view taken along a line XX-XX in FIG. 19.

FIG. 21 is a plan view schematically showing a configuration of a semiconductor substrate in a fifth embodiment of the present invention.

FIG. 22 is a schematic cross sectional view taken along a line XXII-XXII in FIG. 21.

FIG. 23 is a partial cross sectional view schematically showing a configuration of a semiconductor device in a sixth embodiment of the present invention.

FIG. 24 is a schematic flowchart showing a method for manufacturing the semiconductor device in the sixth embodiment of the present invention.

FIG. 25 is a partial cross sectional view schematically showing a first step of the method for manufacturing the semiconductor device in the sixth embodiment of the present invention.

FIG. 26 is a partial cross sectional view schematically showing a second step of the method for manufacturing the semiconductor device in the sixth embodiment of the present invention.

FIG. 27 is a partial cross sectional view schematically showing a third step of the method for manufacturing the semiconductor device in the sixth embodiment of the present invention.

FIG. 28 is a partial cross sectional view schematically showing a fourth step of the method for manufacturing the semiconductor device in the sixth embodiment of the present invention.

### MODES FOR CARRYING OUT THE INVENTION

The following describes an embodiment of the present invention with reference to figures.

### First Embodiment

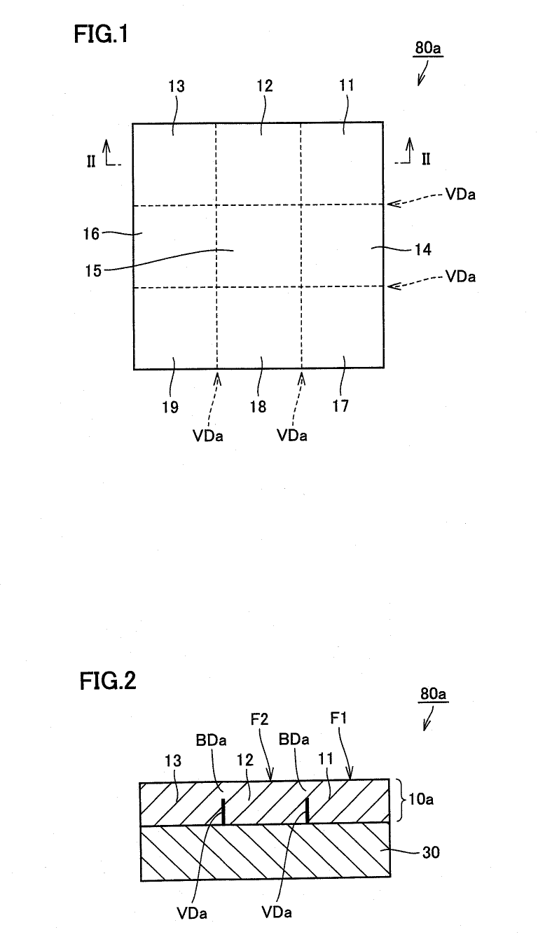

Referring to FIG. 1 and FIG. 2, a semiconductor substrate 80a of the present embodiment has a supporting portion 30 and a supported portion 10a supported by supporting portion 30. Supported portion 10a has SiC substrates 11-19 (silicon carbide substrates).

Supporting portion 30 connects the backside surfaces of SiC substrates 11-19 (surfaces opposite to the surfaces shown in FIG. 1) to one another, whereby SiC substrates 11-19 are fixed to one another. SiC substrates 11-19 respectively have exposed front-side surfaces on the same plane. For example, SiC substrates 11 and 12 respectively have first and second front-side surfaces F1, F2 (FIG. 2). Thus, semiconductor substrate 80a has a surface larger than the surface of each of SiC substrates 11-19. Hence, in the case of using semiconductor substrate 80a, semiconductor devices can be manufactured more effectively than in the case of using each of SiC substrates 11-19 solely.

Further, supporting portion 30 is made of a material having a high heat resistance, is preferably made of a material capable of enduring a temperature of not less than 1800° C. As such a material, silicon carbide, carbon, or a refractory metal can be used, for example. An exemplary refractory metal usable is molybdenum, tantalum, tungsten, niobium, iridium, ruthenium, or zirconium. When silicon carbide is employed as the material of supporting portion 30 from among the materials exemplified above, supporting portion 30 has properties closer to those of SiC substrates 11-19.

In supported portion 10a, gaps VDa exist between SiC substrates 11-19. These gaps VDa are closed at their front-side surface sides (upper sides in FIG. 2) by connecting portions BDa. Each of connecting portions BDa has a portion located between first and second front-side surfaces F1, F2, whereby first and second front-side surfaces F1, F2 are connected to each other smoothly.

Next, a method for manufacturing semiconductor substrate 80a of the present embodiment will be described. For ease of description, only SiC substrates 11 and 12 of SiC substrates 11-19 may be explained, but the same explanation also applies to SiC substrates 13-19.

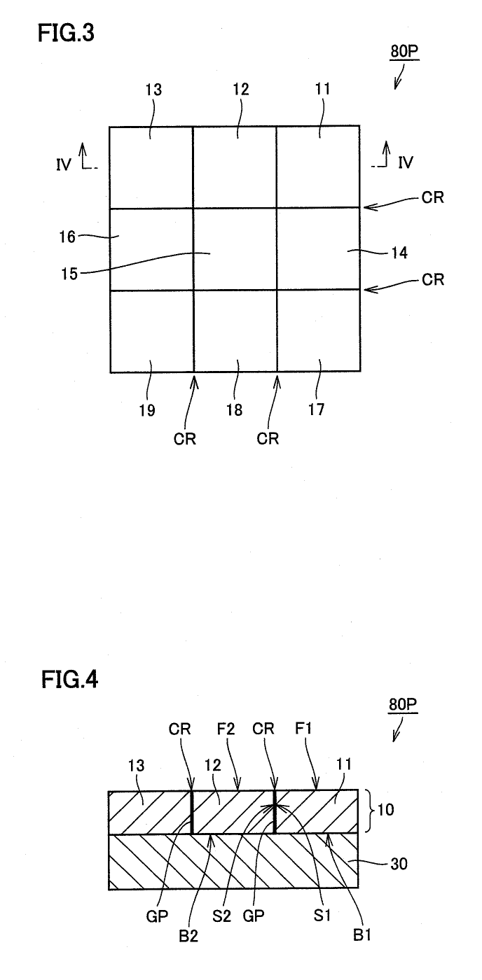

Referring to FIG. 3 and FIG. 4, a combined substrate 80P is prepared. Combined substrate 80P includes supporting portion 30 and a SiC substrate group 10.

SiC substrate group 10 includes SiC substrate 11 (first silicon carbide substrate) and SiC substrate 12 (second silicon carbide substrate). SiC substrate 11 has first backside surface B1 connected to supporting portion 30, first front-side surface F1 opposite to first backside surface B1, and a first side surface S1 connecting first backside surface B1 and first front-side surface F1. SiC substrate 12 has second backside surface B2 connected to supporting portion 30, second front-side surface F2 opposite to second backside surface B2, and a second side surface S2 connecting second backside surface B2 and second front-side surface F2. Second side surface S2 is disposed such that a gap GP having an opening CR between first and second front-side surfaces F1, F2 is formed between first side surface S1 and second side surface S2.

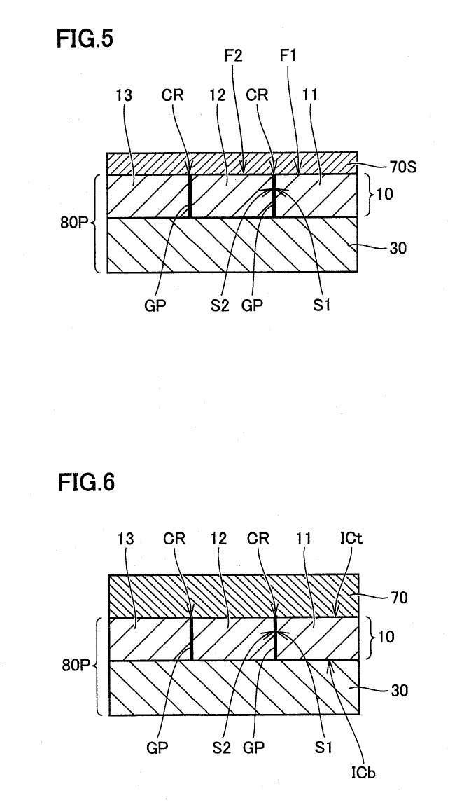

Referring to FIG. 5, as a closing layer for closing gap GP over opening CR, a silicon layer 70S is formed on first and second front-side surfaces F1, F2. As a formation method therefor, a CVD (Chemical Vapor Deposition) method or an evaporation method can be used.

Next, silicon layer 70S is heated to have a temperature equal to or higher than the melting point of silicon. This temperature is preferably 2200° C. or smaller. Further, the atmosphere includes a gas containing carbon. Thus, the gas containing carbon is supplied to silicon layer 70S. An exemplary usable gas containing carbon is propane or acetylene. As such, the gas containing carbon is supplied to silicon layer 70S having the high temperature, thereby reacting the silicon element of silicon layer 70S with the carbon element of the atmosphere.

Referring to FIG. 6, by the reaction, silicon layer 70S is carbonized to form a cover 70 made of silicon carbide and closing gap GP over opening CR.

Next, combined substrate 80P (FIG. 6) thus having cover 70 formed thereon as described above is heated up to a temperature at which silicon carbide can sublime. This heating is performed to cause a temperature gradient in a direction of thickness of the SiC substrate group such that a cover side ICt of SiC substrate group 10, i.e., side facing cover 70, has a temperature lower than the temperature of a support side ICb of SiC substrate group 10, i.e., side facing supporting portion 30. Such a temperature gradient is attained by, for example, heating it to render the temperature of cover 70 lower than that of supporting portion 30.

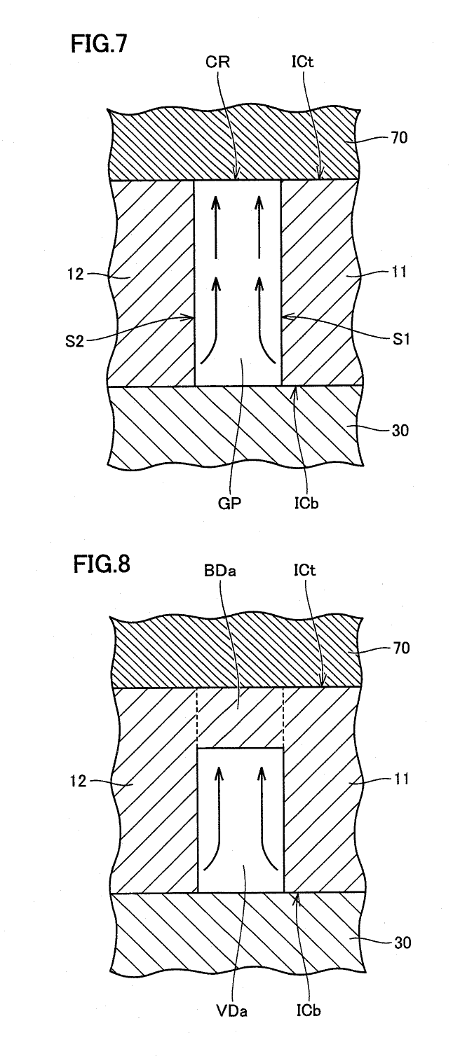

Referring to FIG. 7, as indicated by arrows in the figure, this heating causes sublimation involving mass transfer from a relatively high temperature region close to support side ICb to a relatively low temperature region close to cover side ICt at the surfaces of SiC substrates 11 and 12 in the closed gap GP, i.e., at first and second side surfaces S1, S2. As a result of the mass transfer, in gap GP closed by cover 70, sublimates from first and second side surfaces S1, S2 are deposited on cover 70.

Further, referring to FIG. 8, as a result of the deposition, connecting portion BDa is formed to close opening CR of gap GP (FIG. 7) and accordingly connect first and second side surfaces S1, S2 to each other. As a result, gap GP (FIG. 7) is formed into a gap VDa (FIG. 8) closed by connecting portion BDa.

Preferably, atmosphere in the processing chamber upon the formation of connecting portion BDa is obtained by reducing pressure of atmospheric air. The pressure of the atmosphere is preferably set to be higher than 10⁻¹ Pa and lower than 10⁴ Pa.

The atmosphere described above may be an inert gas atmosphere. An exemplary inert gas usable is a noble gas such as He or Ar; a nitrogen gas; or a mixed gas of the noble gas and nitrogen gas. When using the mixed gas, a ratio of the nitrogen gas is, for example, 60%. Further, the pressure in the processing chamber is preferably 50 kPa or smaller, and is more preferably 10 kPa or smaller.

It should be noted that an experiment was conducted to review heating temperatures. It was found that at 1600° C., connecting portion BDa was not sufficiently formed, and at 3000° C., SiC substrates 11, 12 were damaged, disadvantageously. However, these disadvantages were not found at 1800° C., 2000° C., and 2500° C.

In addition, with the heating temperature being fixed to 2000° C., pressures upon the heating were reviewed. As a result, at 100 kPa, connecting portion BDa was not formed, and at 50 kPa, connecting portion BDa was less likely to be formed, disadvantageously. However, these disadvantages were not found at 10 kPa, 100 Pa, 1 Pa, 0.1 Pa, and 0.0001 Pa.

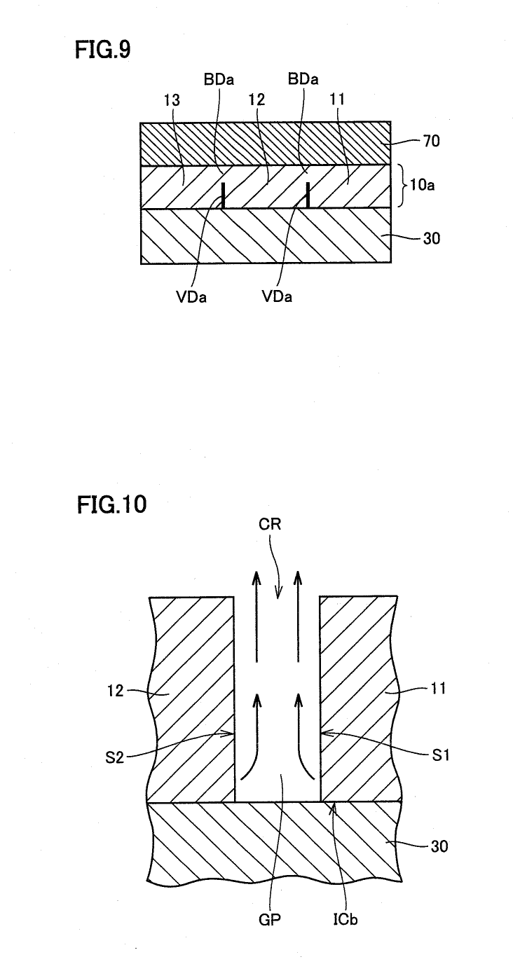

Referring to FIG. 9, after connecting portion BDa is formed, cover 70 is removed. This removal is accomplished by CMP (Chemical Mechanical Polishing), for example. In this way, semiconductor substrate 80a (FIG. 2) is obtained.

The following describes a comparative example (FIG. 10) in which cover 70 does not exist in the step shown in FIG. 7. In this case, because there is no cover 70 for blocking the flow of the gas sublimated from first and second side surfaces S1 and S2, the gas is likely to get out of gap GP. Accordingly, connecting portion BDa (FIG. 8) is less likely to be formed. Hence, opening CR is less likely to be closed.

It should be noted that as a variation of the method for forming the closing layer (FIG. 5: silicon layer 70S), the following method may be used. That is, a silicon layer is first formed which does not fully cover gap GP. Then, this silicon layer is melted and accordingly floated to form a closing layer for closing gap GP. The heating step for melting the silicon layer in this way may be performed as a part of the heating step for carbonizing silicon layer 70S.

Further, as a variation of the method for forming cover 70, there may be used a method in which formation of a silicon layer and carbonization thereof is repeated a plurality of times. Accordingly, the silicon layer carbonized in one carbonizing step is small in thickness, thus achieving more secure carbonization of the silicon layer.

In addition, it is preferable to adjust the thickness of silicon layer 70S such that cover 70 will have a thickness of more than 0.1 μm and less than 1 mm. If the thickness thereof is 0.1 μm or smaller, cover 70 may be discontinuous over opening CR. On the other hand, if the thickness of cover 70 is 1 mm or greater, it takes a long time to remove cover 70.

According to the present embodiment, as shown in FIG. 2, SiC substrates 11 and 12 are combined as one semiconductor substrate 80a through supporting portion 30. Semiconductor substrate 80a includes respective first and second front-side surfaces F1, F2 of the SiC substrates, as its substrate surface on which a semiconductor device such as a transistor is to be formed. In other words, semiconductor substrate 80a has a larger substrate surface than in the case where any of SiC substrates 11 and 12 is solely used. Thus, semiconductor substrate 80a allows semiconductor devices to be manufactured efficiently.

Further, since opening CR (FIG. 4) of gap GP between SiC substrates 11, 12 is closed by connecting portion BDa (FIG. 2), foreign matters are not accumulated in gap GP (FIG. 4) upon manufacturing a semiconductor device using semiconductor substrate 80a. In other words, a semiconductor substrate is obtained which allows for manufacturing of semiconductor devices with a high yield.

Further, cover 70, on which the sublimates (FIG. 8: connecting portion BDa) are deposited to close opening CR (FIG. 7), is made of silicon carbide. Namely, cover 70 and SiC substrates 11, 12 are all made of silicon carbide. Accordingly, cover 70 can be provided with a crystal structure close to the crystal structure of each of SiC substrates 11, 12. Hence, connecting portion BDa formed on cover 70 can be also provided with a crystal structure close to that of each of SiC substrates 11, 12. As a result, the crystal structure of each of SiC substrates 11, 12 and the crystal structure of connecting portion BDa are close to each other, thereby allowing connecting portion BDa to firmly connect SiC substrates 11, 12 to each other.

Further, cover 70 made of silicon carbide is formed using silicon layer 70S, which can be formed more readily as compared with formation of a silicon carbide layer. Accordingly, semiconductor substrate 80a can be manufactured more readily as compared with a case of directly forming a cover formed of silicon carbide.

Further, since cover 70 is formed of silicon carbide, cover 70 is provided with a heat resistance enough to endure a high temperature upon the formation of connecting portion BDa (FIG. 8).

Further, cover 70 made of silicon carbide can be formed readily by carbonizing silicon layer 70S with the gas containing carbon element and supplied to silicon layer 70S.

### Second Embodiment

As a method for manufacturing a semiconductor substrate in the present embodiment, a structure similar to that of FIG. 5 is prepared through steps similar to those in the first embodiment.

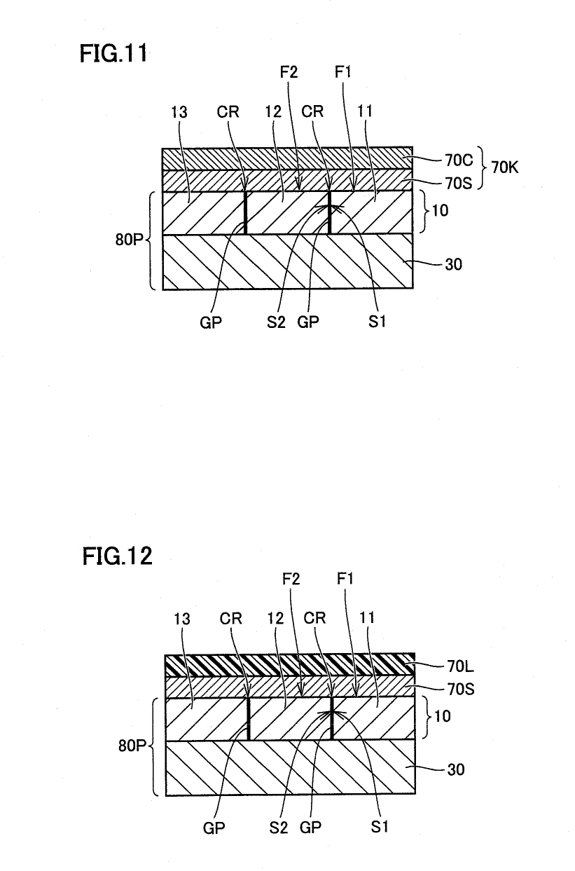

Referring to FIG. 11, a layer made of carbon is deposited on silicon layer 70S using a sputtering method, for example. Accordingly, a carbon layer 70C is formed. In other words, a closing layer 70K constituted by silicon layer 70S and carbon layer 70C is formed to close gap GP over opening CR.

Next, closing layer 70K is heated to have a temperature equal to or higher than the melting point of silicon. This temperature is preferably 2200° C. or smaller. Accordingly, silicon contained in silicon layer 70S and carbon contained in carbon layer 70C are chemically combined. As a result, silicon layer 70S is carbonized, thereby forming cover 70 (FIG. 6) made of silicon carbide and closing gap GP over opening CR. Then, the same steps as those in the first embodiment are performed to obtain semiconductor substrate 80a (FIG. 2).

According to the present embodiment, cover 70 made of silicon carbide can be formed using silicon layer 70S and carbon layer 70C.

The following describes a first variation of the method for forming carbon layer 70C.

Referring to FIG. 12, onto silicon layer 70S, a resist liquid, which is a liquid containing an organic substance, is applied as a fluid 70L containing carbon element. Here, opening CR is adapted to have a sufficiently small width in advance, and the resist liquid is adapted to have a sufficiently large viscosity. Accordingly, the resist liquid applied spans over opening CR and hardly comes into gap GP.

Now, referring to FIG. 11, fluid 70L is carbonized, thereby forming carbon layer 70C. This carbonizing step is performed, for example, as follows.

First, the resist liquid applied (FIG. 12: fluid 70L) is calcined for 10 seconds to 2 hours at 100-300° C. Accordingly, the resist liquid is hardened to form a resist layer.

Then, this resist layer is thermally treated to be carbonized, thereby forming carbon layer 70C (FIG. 11). The thermal treatment is performed under conditions that the atmosphere is an inert gas or nitrogen gas with a pressure not more than the atmospheric pressure, the temperature is more than 300° C. and less than 1400° C., and the treatment time is more than one minute and less than 12 hours. If the temperature is equal to or smaller than 300° C., the carbonization is likely to be insufficient. On the other hand, if the temperature is equal to or greater than 1400° C., the front-side surfaces of SiC substrates 11 and 12 are likely to be deteriorated. Further, if the treatment time is equal to or shorter than one minute, the carbonization of the resist layer is likely to be insufficient. Hence, a longer treatment time is preferable. However, a sufficient treatment time is of less than 12 hours at maximum.

According to the present variation, the formation of carbon layer 70C can be accomplished by the readily implementable steps such as the application of the resist liquid serving as fluid 70L, and the carbonization thereof. Furthermore, the resist liquid is a liquid and is therefore uniformly applied readily.

The following describes a second variation of the method for forming carbon layer 70C. In the present variation, instead of the resist liquid (the above-described first variation), an adhesive agent is used as fluid 70L (FIG. 12). This adhesive agent is a suspension (carbon adhesive agent) containing carbon powders.

The carbon adhesive agent applied is calcined at 50° C.-400° C. for 10 seconds to 12 hours. Accordingly, the carbon adhesive agent is hardened to form an adhesive layer.

Then, this adhesive layer is thermally treated to be carbonized, thereby forming carbon layer 70C. The thermal treatment is performed under conditions that the atmosphere is an inert gas or nitrogen gas with a pressure not more than the atmospheric pressure, the temperature is more than 300° C. and less than 1400° C., and the treatment time is more than one minute and less than 12 hours. If the temperature is equal to or smaller than 300° C., the carbonization is likely to be insufficient. On the other hand, if the temperature is equal to or greater than 1400° C., the front-side surfaces of SiC substrates 11 and 12 are likely to be deteriorated. Further, if the treatment time is equal to or shorter than one minute, the carbonization of the adhesive layer is likely to be insufficient. Hence, a longer treatment time is preferable. However, a sufficient treatment time is of less than 12 hours at maximum. Thereafter, steps similar to the above-described steps in the present embodiment are performed.

According to the present variation, by removing liquid component of the suspension containing carbon powders, fluid 70L can be carbonized readily. In other words, the material of carbon layer 70C is surely carbon.

It should be noted that as a variation of closing layer 70K (FIG. 11), there may be employed a configuration in which the location of silicon layer 70S and the location of carbon layer 70C are replaced with each other.

Further, as a variation of the method for forming closing layer 70K (FIG. 11), the following method may be used. That is, a layered film of a silicon layer and a carbon layer is formed not to fully close gap GP. Then, the silicon layer in the layered film is melted and accordingly floated to form a closing layer for closing gap GP. The heating step for melting the silicon layer can be performed as a part of the heating step for carbonizing silicon layer 70S.

Further, as a variation of the method for forming cover 70, there may be used a closing layer including three or more layers, instead of closing layer 70K including one silicon layer 70S and one carbon layer 70C, i.e., closing layer 70K including two layers. Accordingly, each layer in the closing layer has a small thickness, thus allowing silicon and carbon to be chemically combined with each other in the closing layer more securely.

### Third Embodiment

In the present embodiment, the following fully describes a particular case where supporting portion 30 is made of silicon carbide in the method for manufacturing combined substrate 80P (FIG. 3, FIG. 4) used in the first or second embodiment. For ease of description, only SiC substrates 11 and 12 of SiC substrates 11-19 (FIG. 3, FIG. 4) may be explained, but the same explanation also applies to SiC substrates 13-19.

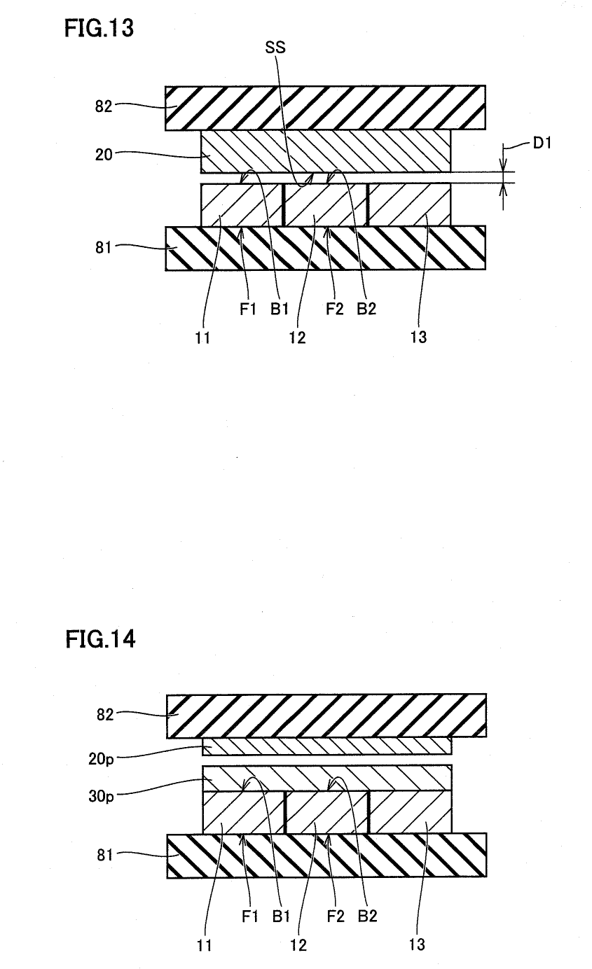

Referring to FIG. 13, SiC substrates 11 and 12 are prepared each of which has a single-crystal structure. Specifically, for example, SiC substrates 11 and 12 are prepared by cutting, along the (03-38) plane, a SiC ingot grown in the (0001) plane in the hexagonal system. Preferably, each of backside surfaces B1 and B2 has a roughness Ra of not more than 100 μm.

Next, SiC substrates 11 and 12 are placed on a first heating member 81 in the processing chamber with each of backside surfaces B1 and B2 being exposed in one direction (upward in FIG. 13). Namely, when viewed in a plan view, SiC substrates 11 and 12 are arranged side by side.

Preferably, this arrangement is accomplished by disposing backside surfaces B1 and B2 on the same flat plane or by disposing first and second front-side surfaces F1, F2 on the same flat plane.

Further, a minimum space between SiC substrates 11 and 12 (minimum space in a lateral direction in FIG. 13) is preferably 5 mm or smaller, more preferably, 1 mm or smaller, and further preferably 100 μm or smaller, and particularly preferably 10 μm or smaller. Specifically, for example, the substrates, which have the same rectangular shape, are arranged in the form of a matrix with a space of 1 mm or smaller therebetween.

Next, supporting portion 30 (FIG. 2) is formed to connect backside surfaces B1 and B2 to each other in the following manner.

First, each of backside surfaces B1 and B2 exposed in the one direction (upward in FIG. 13) and a surface SS of a solid source material 20 disposed in the one direction (upward in FIG. 13) relative to backside surfaces B1 and B2 are arranged face to face with a space D1 provided therebetween. Preferably, space D1 has an average value of not less than 1 μm and not more than 1 cm.

Solid source material 20 is made of SiC, and is preferably a piece of solid matter of silicon carbide, specifically, a SiC wafer, for example. Solid source material 20 is not particularly limited in crystal structure of SiC. Further, surface SS of solid source material 20 preferably has a roughness Ra of 1 mm or smaller.

In order to provide space D1 (FIG. 13) more securely, there may be used spacers 83 (FIG. 16) each having a height corresponding to space D1. This method is particularly effective when the average value of space D1 is approximately 100 μm.

Next, SiC substrates 11 and 12 are heated by first heating member 81 to a predetermined substrate temperature. On the other hand, solid source material 20 is heated by a second heating member 82 to a predetermined source material temperature. When solid source material 20 is thus heated to the source material temperature, SiC is sublimated at surface SS of the solid source material to generate a sublimate, i.e., gas. The gas thus generated is supplied onto backside surfaces B1 and B2 in the one direction (from upward in FIG. 13).

Preferably, the substrate temperature is set to be lower than the source material temperature. More preferably, a difference between the substrate temperature and the source material temperature is set to cause a temperature gradient of not less than 0.1° C./mm and not more than 100° C./mm in a direction of thickness of each of SiC substrates 11, 12 and solid source material 20 (vertical direction in FIG. 13). Further, the substrate temperature is preferably 1800° C. or greater and 2500° C. or smaller.

Referring to FIG. 14, the gas supplied as described above is solidified and accordingly recrystallized on each of backside surfaces B1 and B2. In this way, a supporting portion 30p is formed to connect backside surfaces B1 and B2 to each other. Further, solid source material 20 (FIG. 13) is consumed and is reduced in size to be a solid source material 20p.

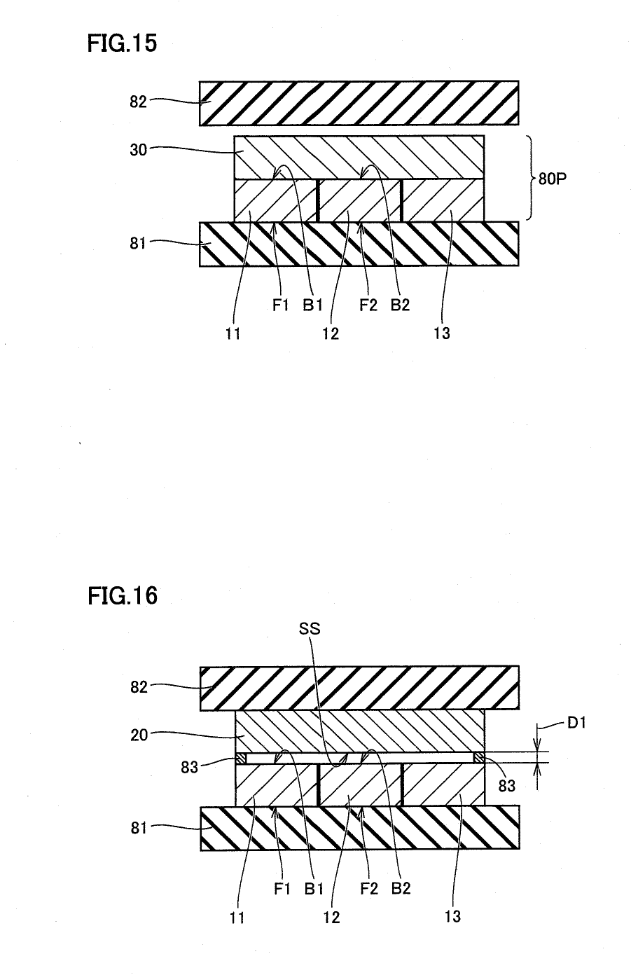

Referring to FIG. 15 mainly, as the sublimation develops, solid source material 20p (FIG. 14) is run out. In this way, supporting portion 30 is formed to connect backside surfaces B1 and B2 to each other.

Upon the formation of supporting layer 30, the atmosphere in the processing chamber is preferably obtained by reducing the pressure of the atmospheric air. The pressure of the atmosphere is preferably higher than 10⁻¹ Pa and lower than 10⁴ Pa.

The atmosphere described above may be an inert gas atmosphere. An exemplary inert gas usable is a noble gas such as He or Ar; a nitrogen gas; or a mixed gas of the noble gas and nitrogen gas. When using the mixed gas, a ratio of the nitrogen gas is, for example, 60%. Further, the pressure in the processing chamber is preferably 50 kPa or smaller, and is more preferably 10 kPa or smaller.

Further, supporting portion 30 preferably has a single-crystal structure. More preferably, supporting portion 30 on backside surface B1 has a crystal plane inclined by 10° or smaller relative to the crystal plane of backside surface B1, and supporting portion 30 on backside surface B2 has a crystal plane inclined by 10° relative to the crystal plane of backside surface B2. These angular relations can be readily realized by expitaxially growing supporting portion 30 on backside surfaces B1 and B2.

The crystal structure of each of SiC substrates 11, 12 is preferably of hexagonal system, and is more preferably 4H—SiC or 6H—SiC. Moreover, it is preferable that SiC substrates 11, 12 and supporting portion 30 be made of SiC single crystal having the same crystal structure.

Further, the concentration in each of SiC substrates 11 and 12 is preferably different from the impurity concentration of supporting portion 30. More preferably, supporting portion 30 has an impurity concentration higher than that of each of SiC substrates 11 and 12. It should be noted that each of SiC substrates 11, 12 has an impurity concentration of, for example, not less than 5×10¹⁶ cm⁻³ and not more than 5×10¹⁹ cm⁻³. Moreover, supporting portion 30 has an impurity concentration of, for example, not less than 5×10¹⁶ cm⁻³ and not more than 5×10²¹ cm⁻³. As the impurity, nitrogen or phosphorus can be used, for example.

Further, preferably, first front-side surface F1 has an off angle of 50° or greater and 65° or smaller relative to the {0001} plane of SiC substrate 11 and second front-side surface F2 has an off angle of 50° or greater and 65° or smaller relative to the {0001} plane of the SiC substrate.

More preferably, the off orientation of first front-side surface F1 forms an angle of 5° or smaller relative to the <1-100> direction of SiC substrate 11, and the off orientation of second front-side surface F2 forms an angle of 5° or smaller with the <1-100> direction of substrate 12.

Further, first front-side surface F1 preferably has an off angle of not less than −3° and not more than 5° relative to the {03-38} plane in the <1-100> direction of SiC substrate 11, and second front-side surface F2 preferably has an off angle of not less than −3° and not more than 5° relative to the {03-38} plane in the <1-100> direction of SiC substrate 12.

It should be noted that the “off angle of first front-side surface F1 relative to the {03-38} plane in the <1-100> direction” refers to an angle formed by an orthogonal projection of a normal line of first front-side surface F1 to a projection plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction. This is similar in the “off angle of second front-side surface F2 relative to the {03-38} plane in the <1-100> direction”.

Further, the off orientation of first front-side surface F1 forms an angle of 5° or smaller with the <11-20> direction of substrate 11. The off orientation of second front-side surface F2 forms an angle of 5° or smaller with the <11-20> direction of substrate 12.

According to the present embodiment, since supporting portion 30 formed on backside surfaces B1 and B2 is also made of SiC as with SiC substrates 11 and 12, physical properties of the SiC substrates and supporting portion 30 are close to one another. Accordingly, warpage or cracks of combined substrate 80P (FIG. 3, FIG. 4) or semiconductor substrate 80a (FIG. 1, FIG. 2) resulting from a difference in physical property therebetween can be suppressed.

Further, utilization of the sublimation method allows supporting portion 30 to be formed fast with high quality. When the sublimation method thus utilized is a close-spaced sublimation method, supporting portion 30 can be formed more uniformly.

Further, when the average value of space D1 (FIG. 13) between each of backside surfaces B1 and B2 and the surface of solid source material 20 is 1 cm or smaller, distribution in film thickness of supporting portion 30 can be reduced. So far as the average value of space D1 is 1 μm or greater, a space for sublimation of SiC can be sufficiently secured.

Meanwhile, in the step of forming supporting portion 30, the temperatures of SiC substrates 11 and 12 are set lower than that of solid source material 20 (FIG. 13). This allows the sublimated SiC to be efficiently solidified on SiC substrates 11 and 12.

Further, the step of placing SiC substrates 11 and 12 is preferably performed to allow the minimum space between SiC substrates 11 and 12 to be 1 mm or smaller. Accordingly, supporting portion 30 can be formed to connect backside surface B1 of SiC substrate 11 and backside surface B2 of SiC substrate 12 to each other more securely.

Further, supporting portion 30 preferably has a single-crystal structure. Accordingly, supporting portion 30 has physical properties close to the physical properties of SiC substrates 11 and 12 each having a single-crystal structure.

More preferably, supporting portion 30 on backside surface B1 has a crystal plane inclined by 10° or smaller relative to that of backside surface B1. Further, supporting portion 30 on backside surface B2 has a crystal plane inclined by 10° or smaller relative to that of backside surface B2. Accordingly, supporting portion 30 has anisotropy close to that of each of SiC substrates 11 and 12.

Further, preferably, each of SiC substrates 11 and 12 has an impurity concentration different from that of supporting portion 30. Accordingly, there can be obtained semiconductor substrate 80a (FIG. 2) having a structure of two layers with different impurity concentrations.

Furthermore, the impurity concentration in supporting portion 30 is preferably higher than the impurity concentration in each of SiC substrates 11 and 12. This allows the resistivity of supporting portion 30 to be smaller than those of SiC substrates 11 and 12. Accordingly, there can be obtained semiconductor substrate 80a suitable for manufacturing of a semiconductor device in which a current flows in the thickness direction of supporting portion 30, i.e., a semiconductor device of vertical type.

Meanwhile, preferably, first front-side surface F1 has an off angle of not less than 50° and not more than 65° relative to the {0001} plane of SiC substrate 11 and second front-side surface F2 has an off angle of not less than 50° and not more than 65° relative to the {0001} plane of SiC substrate 12. This achieves further improved channel mobility in each of first and second front-side surfaces F1, F2, as compared with a case where each of first and second front-side surfaces F1, F2 corresponds to the {0001} plane.

More preferably, the off orientation of first front-side surface F1 forms an angle of not more than 5° with the <1-100> direction of SiC substrate 11, and the off orientation of second front-side surface F2 forms an angle of not more than 5° with the <1-100> direction of SiC substrate 12. This achieves further improved channel mobility in each of first and second front-side surfaces F1, F2.

Further, first front-side surface F1 preferably has an off angle of not less than −3° and not more than 5° relative to the {03-38} plane in the <1-100> direction of SiC substrate 11, and second front-side surface F2 preferably has an off angle of not less than −3° and not more than 5° relative to the {03-38} plane in the <1-100> direction of SiC substrate 12. This achieves further improved channel mobility in each of first and second front-side surfaces F1, F2.

Further, preferably, the off orientation of first front-side surface F1 forms an angle of not more than 5° with the <11-20> direction of SiC substrate 11, and the off orientation of second front-side surface F2 forms an angle of not more than 5° with the <11-20> direction of SiC substrate 12. This achieves further improved channel mobility in each of first and second front-side surfaces F1, F2, as compared with a case where each of first and second front-side surfaces F1, F2 corresponds to the {0001} plane.

In the description above, the SiC wafer is exemplified as solid source material 20, but solid source material 20 is not limited to this and may be a SiC powder or a SiC sintered compact, for example.

Further, as first and second heating members 81, 82, any heating members can be used as long as they are capable of heating a target object. For example, the heating members can be of resistive heating type employing a graphite heater, or of inductive heating type.

Meanwhile, in FIG. 13, the space is provided between each of backside surfaces B1 and B2 and surface SS of solid source material 20 to extend therealong entirely. However, a space may be provided between each of backside surfaces B1 and B2 and surface SS of solid source material 20 while each of backside surface B1 and B2 and surface SS of solid source material 20 are partially in contact with each other. The following describes two variations corresponding to this case.

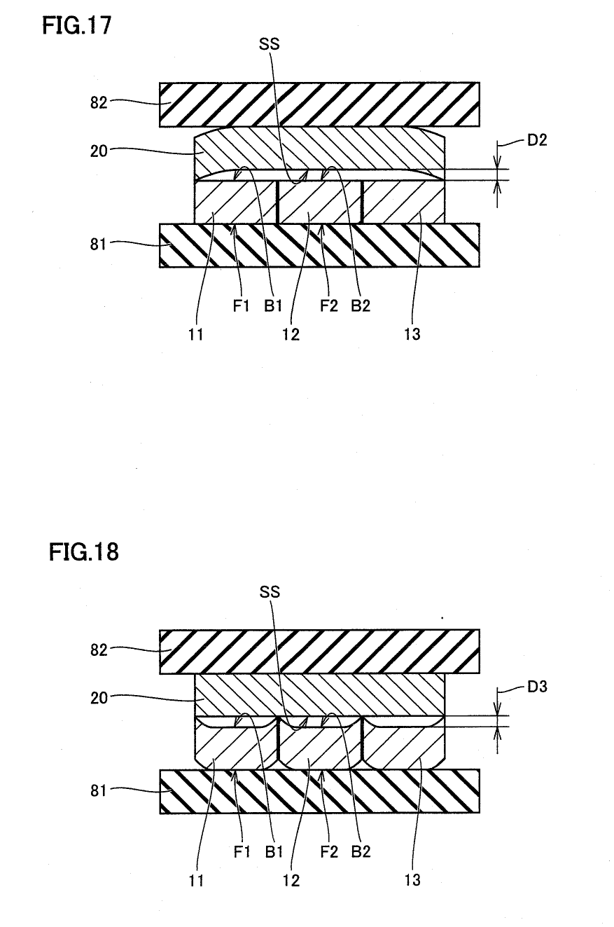

Referring to FIG. 17, in this variation, the space is secured by warpage of the SiC wafer serving as solid source material 20. More specifically, in the present variation, there is provided a space D2 that is locally zero but surely has an average value exceeding zero. Further, as with the average value of space D1, space D2 preferably has an average value of not less than 1 μm and not more than 1 cm.

Referring to FIG. 18, in this variation, the space is secured by warpage of each of SiC substrates 11-13. More specifically, in the present variation, there is provided a space D3 that is locally zero but surely has an average value exceeding zero. Further, as with the average value of space D1, space D3 preferably has an average value of not less than 1 μm and not more than 1 cm.

In addition, the space may be secured by combination of the respective methods shown in FIG. 17 and FIG. 18, i.e., by both the warpage of the SiC wafer serving as solid source material 20 and the warpage of each of SiC substrates 11-13.

Each of the above-described methods shown in FIG. 17 and FIG. 18 or the combination of these methods is particularly effective when the average value of the space is not more than 100 μm.

### Fourth Embodiment

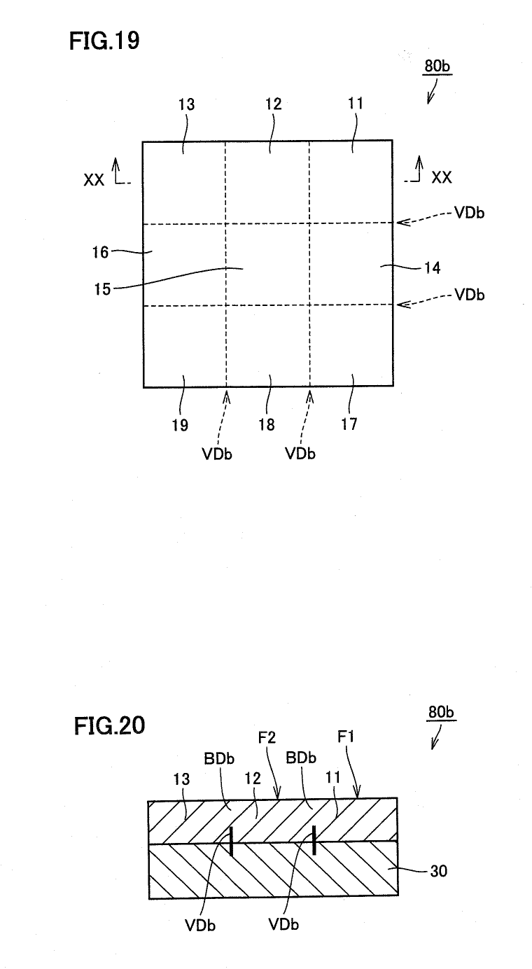

Referring to FIG. 19 and FIG. 20, a semiconductor substrate 80b of the present embodiment has gaps VDb closed by connecting portions BDb, instead of gaps VDa (FIG. 2: the first embodiment) closed by connecting portions BDa.

The following describes a method for manufacturing semiconductor substrate 80b.

First, for example, by the method described in the third embodiment, combined substrate 80P (FIG. 3, FIG. 4) having supporting portion 30 made of SiC is formed. Using combined substrate 80P thus formed, the steps are performed up to the step shown in FIG. 8, in accordance with the method described in the first embodiment.

In the present embodiment, supporting portion 30 is made of SiC, and even after each connecting portion BDa is formed as shown in FIG. 8, the mass transfer involved with the sublimation continues. As a result, sublimation also takes place from supporting portion 30 into closed gap VDa to a considerable extent. In other words, sublimates from supporting portion 30 are deposited onto connecting portion BDa. This brings a part of gap VDa located between SiC substrates 11 and 12 into supporting portion 30, thereby obtaining gap VDb (FIG. 20) closed by connecting portion BDb.

According to semiconductor substrate 80b (FIG. 20) of the present embodiment, there can be formed connecting portion BDb thicker than connecting portion BDa of semiconductor substrate 80a (FIG. 2).

### Fifth Embodiment

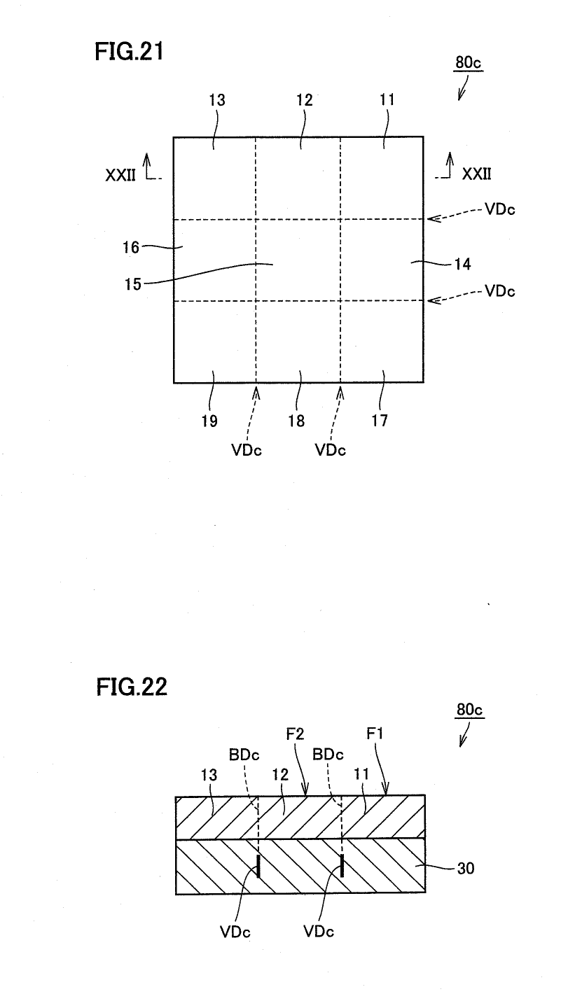

Referring to FIG. 21 and FIG. 22, a semiconductor substrate 80c of the present embodiment has gaps VDc closed by connecting portions BDc instead of gaps VDb (FIG. 20: the fourth embodiment) closed by connecting portion BDb. Semiconductor substrate 80c is obtained using a method similar to that of the fourth embodiment, i.e., by bringing entire gaps VDa (FIG. 2) into supporting portion 30 through the locations of gaps VDb (FIG. 20).

According to the present embodiment, there can be formed each connecting portion BDc thicker than each connecting portion BDb of the fourth embodiment.

It should be noted that gap VDc may be brought to reach the side of the backside surfaces (lower side in FIG. 22) by causing the mass transfer resulting from the sublimation in each gap VDc while causing the side of the front-side surfaces of semiconductor substrate 80c (sides including first and second front-side surfaces F1, F2 of FIG. 22) to have a temperature lower than that of the side of the backside surfaces (lower side in FIG. 22). Accordingly, gap VDc thus closed serves as a recess at the side of the backside surfaces. This recess may be removed by polishing.

### Sixth Embodiment

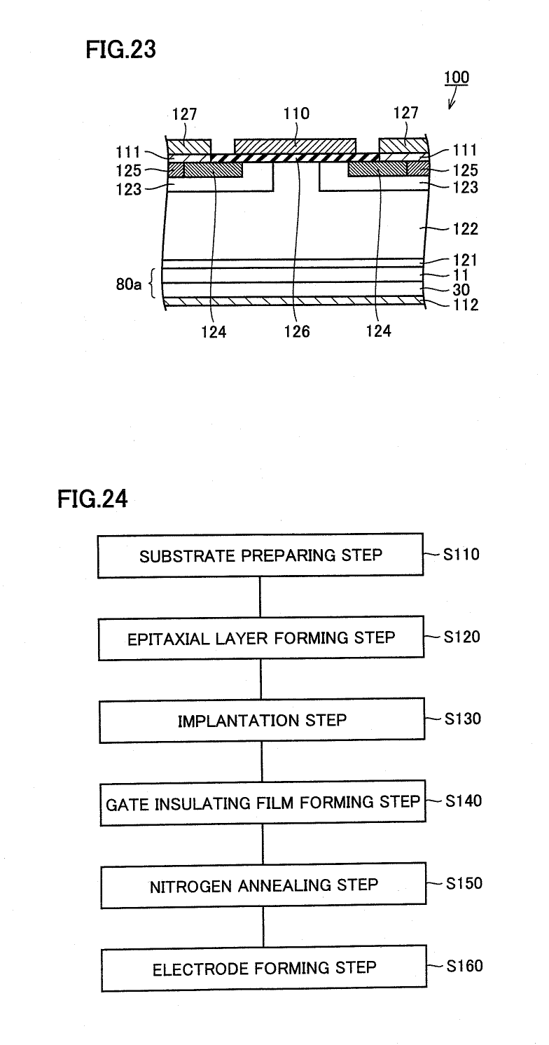

Referring to FIG. 23, a semiconductor device 100 of the present embodiment is a DiMOSFET (Double Implanted Metal Oxide Semiconductor Field Effect Transistor) of vertical type, and has a semiconductor substrate 80a, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112.

In the present embodiment, semiconductor substrate 80a has n type conductivity, and has supporting portion 30 and SiC substrate 11 as described in the first embodiment. Drain electrode 112 is provided on supporting portion 30 to interpose supporting portion 30 between drain electrode 112 and SiC substrate 11. Buffer layer 121 is provided on SiC substrate 11 to interpose SiC substrate 11 between buffer layer 121 and supporting portion 30.

Buffer layer 121 has n type conductivity, and has a thickness of, for example, 0.5 μm. Further, impurity with n type conductivity in buffer layer 121 has a concentration of, for example, 5×10¹⁷ cm⁻³.

Reverse breakdown voltage holding layer 122 is formed on buffer layer 121, and is made of silicon carbide with n type conductivity. For example, reverse breakdown voltage holding layer 122 has a thickness of 10 μm, and includes a conductive impurity of n type at a concentration of 5×10¹⁵ cm⁻³.

Reverse breakdown voltage holding layer 122 has a surface in which the plurality of p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. An oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

The maximum value of the nitrogen atom concentration is 1×10²¹ cm⁻³ or greater in a region distant away by not more than 10 nm from an interface between oxide film 126 and each of n⁺ regions 124, p⁺ regions 125, p regions 123 and reverse breakdown voltage holding layer 122, which serve as semiconductor layers. This achieves improved mobility particularly in a channel region below oxide film 126 (a contact portion of each p region 123 with oxide film 126 between each of n⁺ regions 124 and reverse breakdown voltage holding layer 122).

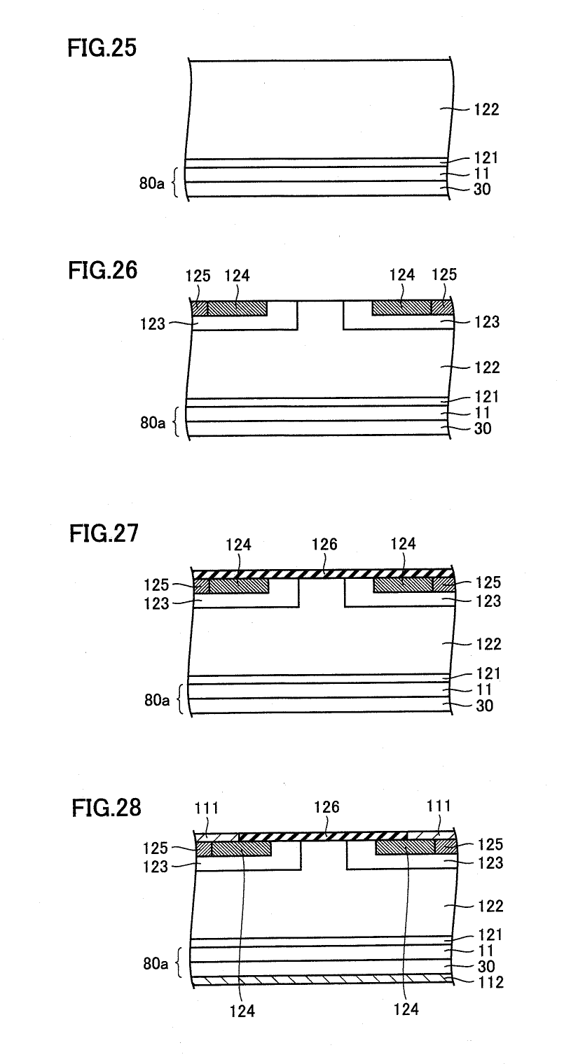

The following describes a method for manufacturing a semiconductor device 100. It should be noted that FIG. 25-FIG. 28 show steps only in the vicinity of SiC substrate 11 of SiC substrates 11-19 (FIG. 1), but the same steps are performed also in the vicinity of each of SiC substrates 12-19.

First, in a substrate preparing step (step S110: FIG. 24), semiconductor substrate 80a (FIG. 1 and FIG. 2) is prepared. Semiconductor substrate 80a has n type conductivity.

Referring to FIG. 25, in an epitaxial layer forming step (step S120: FIG. 24), buffer layer 121 and reverse breakdown voltage holding layer 122 are formed as follows.

First, buffer layer 121 is formed on SiC substrate 11 of semiconductor substrate 80a. Buffer layer 121 is made of silicon carbide of n type conductivity, and is an epitaxial layer having a thickness of 0.5 μm, for example. Buffer layer 121 has a conductive impurity at a concentration of, for example, 5×10¹⁷ cm⁻³.

Next, reverse breakdown voltage holding layer 122 is formed on buffer layer 121. Specifically, a layer made of silicon carbide of n type conductivity is formed using an epitaxial growth method. Reverse breakdown voltage holding layer 122 has a thickness of, for example, 10 μm. Further, reverse breakdown voltage holding layer 122 includes an impurity of n type conductivity at a concentration of, for example, 5×10¹⁵ cm⁻³.

Referring to FIG. 26, an implantation step (step S130: FIG. 24) is performed to form p regions 123, n⁺ regions 124, and p⁺ regions 125 as follows.

First, an impurity of p type conductivity is selectively implanted into portions of reverse breakdown voltage holding layer 122, thereby forming p regions 123. Then, a conductive impurity of n type is selectively implanted to predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed. For example, the annealing is performed in argon atmosphere at a heating temperature of 1700° C. for 30 minutes.

Referring to FIG. 27, a gate insulating film forming step (step S140: FIG. 24) is performed. Specifically, oxide film 126 is formed to cover reverse breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitrogen annealing step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

Referring to FIG. 28, an electrode forming step (step S160: FIG. 24) is performed to form source electrodes 111 and drain electrode 112 in the following manner.

First, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

Referring to FIG. 23 again, upper source electrodes 127 are formed on source electrodes 111. Further, drain electrode 112 is formed on the backside surface of semiconductor substrate 80a. Further, gate electrode 110 is formed on oxide film 126. In this way, semiconductor device 100 is obtained.

It should be noted that a configuration may be employed in which conductive types are opposite to those in the present embodiment. Namely, a configuration may be employed in which p type and n type are replaced with each other.

Further, the semiconductor substrate for use in fabricating semiconductor device 100 is not limited to semiconductor substrate 80a of the first embodiment, and may be, for example, each of the semiconductor substrates obtained according to the second to fifth embodiments and their variations.

Further, the DiMOSFET of vertical type has been exemplified, but another semiconductor device may be manufactured using the semiconductor substrate of the present invention. For example, a RESURF-JFET (Reduced Surface Field-Junction Field Effect Transistor) or a Schottky diode may be manufactured.

### APPENDIX 1

The semiconductor substrate of the present invention is manufactured in the following method for manufacturing.

First, a combined substrate (80P) is prepared which has a supporting portion (FIG. 4: 30), a first silicon carbide substrate (11) having a single-crystal structure, and a second silicon carbide substrate (12) having a single-crystal structure. The first silicon carbide substrate has a first backside surface (B1) connected to the supporting portion, a first front-side surface (F1) opposite to the first backside surface, and a first side surface (S1) connecting the first backside surface and the first front-side surface. The second silicon carbide substrate has a second backside surface (B2) connected to the supporting portion, a second front-side surface (F2) opposite to the second backside surface, and a second side surface (S2) connecting the second backside surface and the second surface. The second side surface is disposed such that a gap (GP) having an opening (CR) between the first and second front-side surfaces is formed between the first side surface and the second side surface. Then, a closing layer is formed to close the gap over the opening. The closing layer at least includes a silicon layer (FIG. 5: 70S). Then, in order to form a cover (FIG. 6: 70) made of silicon carbide and closing the gap over the opening, the silicon layer is carbonized. Then, by accumulating a sublimate from the first and second side surfaces onto the cover, a connecting portion (FIG. 8: BDa) is formed to connect the first and second side surface so as to close the opening. The cover is removed after the step of forming the connecting portion.

### APPENDIX 2

The semiconductor device of the present invention is fabricated using a semiconductor substrate fabricated using the following method for manufacturing.

First, a combined substrate (80P) is prepared which has a supporting portion (FIG. 4: 30), a first silicon carbide substrate (11) having a single-crystal structure, and a second silicon carbide substrate (12) having a single-crystal structure. The first silicon carbide substrate has a first backside surface (B1) connected to the supporting portion, a first front-side surface (F1) opposite to the first backside surface, and a first side surface (S1) connecting the first backside surface and the first front-side surface. The second silicon carbide substrate has a second backside surface (B2) connected to the supporting portion, a second front-side surface (F2) opposite to the second backside surface, and a second side surface (S2) connecting the second backside surface and the second surface. The second side surface is disposed such that a gap (GP) having an opening (CR) between the first and second front-side surfaces is formed between the first side surface and the second side surface. Then, a closing layer is formed to close the gap over the opening. The closing layer at least includes a silicon layer (FIG. 5: 70S). Then, in order to form a cover (FIG. 6: 70) made of silicon carbide and closing the gap over the opening, the silicon layer is carbonized. Then, by accumulating a sublimate from the first and second side surfaces onto the cover, a connecting portion (FIG. 8: BDa) is formed to connect the first and second side surface so as to close the opening. The cover is removed after the step of forming the connecting portion.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### INDUSTRIAL APPLICABILITY

A method for manufacturing a semiconductor substrate in the present invention is advantageously applicable particularly to a method for manufacturing a semiconductor substrate including a portion made of silicon carbide having a single-crystal structure.

### DESCRIPTION OF THE REFERENCE SIGNS

10: SiC substrate group; 10a: supported portion; 11: SiC substrate (first silicon carbide substrate); 12: SiC substrate (second silicon carbide substrate); 13-19: SiC substrate; 20, 20p: solid source material; 30, 30p: supporting portion; 70C: carbon layer; 70K: closing layer; 70L: fluid; 70S: silicon layer (closing layer); 80a-80c: semiconductor substrate; 80P: combined substrate; 81: first heating member; 82: second heating member; 100: semiconductor device.

1: A method for manufacturing a semiconductor substrate, comprising the steps of:
preparing a combined substrate having a supporting portion, a first silicon carbide substrate having a single-crystal structure, and a second silicon carbide substrate having a single-crystal structure, said first silicon carbide substrate having a first backside surface connected to said supporting portion, a first front-side surface opposite to said first backside surface, and a first side surface connecting said first backside surface and said first front-side surface, said second silicon carbide substrate having a second backside surface connected to said supporting portion, a second front-side surface opposite to said second backside surface, and a second side surface connecting said second backside surface and said second front-side surface, said second side surface being disposed such that a gap having an opening between said first and second front-side surfaces is formed between said first side surface and said second side surface;
forming a closing layer for closing said gap over said opening, said closing layer including at least a silicon layer;
carbonizing said silicon layer to form a cover made of silicon carbide and closing said gap over said opening;
forming a connecting portion for connecting said first and second side surfaces so as to close said opening by depositing a sublimate from said first and second side surfaces onto said cover; and
removing said cover after the step of forming said connecting portion.

2: The method for manufacturing the semiconductor substrate according to claim 1, wherein the step of carbonizing said silicon layer includes the step of supplying said silicon layer with a gas containing carbon element.

3: The method for manufacturing the semiconductor substrate according to claim 1, wherein:
the step of forming said closing layer includes the step of providing a carbon layer, and
the step of carbonizing said silicon layer includes the step of chemically combining silicon contained in said silicon layer with carbon contained in said carbon layer.

4: The method for manufacturing the semiconductor substrate according to claim 3, wherein the step of providing said carbon layer includes the step of depositing a layer made of carbon.

5: The method for manufacturing the semiconductor substrate according to claim 3, wherein the step of providing said carbon layer includes steps of: applying a fluid containing carbon element; and carbonizing said fluid.

6: The method for manufacturing the semiconductor substrate according to claim 5, wherein said fluid is a liquid containing an organic substance.

7: The method for manufacturing the semiconductor substrate according to claim 5, wherein said fluid is a suspension containing a carbon powder.

8: The method for manufacturing the semiconductor substrate according to claim 1, wherein said supporting portion is made of silicon carbide.

9: The method for manufacturing the semiconductor substrate according to claim 8, further comprising the step of depositing the sublimate from said supporting portion onto said connecting portion in said gap having said opening closed by said connecting portion.

10: The method for manufacturing the semiconductor substrate according to claim 9, wherein the step of depositing the sublimate from said supporting portion onto said connecting portion is performed to bring, into said supporting portion, the whole of said gap having said opening closed by said connecting portion.

11: The method for manufacturing the semiconductor substrate according to claim 1, further comprising the step of polishing each of said first and second front-side surfaces.

12: The method for manufacturing the semiconductor substrate according to claim 1, wherein each of said first and second backside surfaces is a surface formed through slicing.

13: The method for manufacturing the semiconductor substrate according to claim 1, wherein the step of forming said connecting portion is performed in an atmosphere having a pressure higher than 10⁻¹ Pa and lower than 10⁴ Pa.
